(19) United States
(12) Patent Application Publication
(10) Pub. No.: US 2013/0167917 A1
(43) Pub. Date: Jul. 4, 2013

(54) THIN FILM TYPE SOLAR CELLS AND MANUFACTURING METHOD THEREOF

(71) Applicants: Seung-Yeop Myong, Seoul (KR); La-Sun Jeon, Seoul (KR)

(72) Inventors: Seung-Yeop Myong, Seoul (KR); La-Sun Jeon, Seoul (KR)

(21) Appl. No.: 13/630,589

(22) Filed: Sep. 28, 2012

(30) Foreign Application Priority Data
Sep. 30, 2011 (KR) 10-2011-0099662

(51) Int. Cl. H01L 31/065

(52) U.S. Cl. 136/255

(57) ABSTRACT

Disclosed is a thin film silicon solar cell including: a substrate; a first electrode which is stacked on the substrate; a unit cell which is stacked on the first electrode; and a second electrode which is stacked on the unit cell, wherein the unit cell includes a p-type window layer, an i-type photoelectric conversion layer and an n-type layer, and wherein the n-type layer includes an n-type silicon alloy reflector profiled such that a concentration of a refractive index reduction element is changed gradually or alternately with the increase in a distance from a light incident side.

### CROSS-REFERENCE TO RELATED APPLICATION

This application claims priority under 35 U.S.C. §119(a) from Republic of Korea Patent Application No. 10-2011-0099662 filed on Sep. 30, 2011, which is incorporated by reference herein in its entirety.

### FIELD OF THE INVENTION

This embodiment relates to a thin film silicon solar cell and a manufacturing method thereof, and more particularly to a thin film silicon solar cell having improved photoelectric conversion efficiency and a manufacturing method thereof.

### DESCRIPTION OF THE RELATED ART

An amorphous silicon (a-Si) solar cell was first developed in 1976 and has been being researched because hydrogenated amorphous silicon (a-Si:H) has a high photosensitivity in the visible light region, easiness to adjust an optical band gap, and a large area processability at a low cost and low temperature.

However, it was discovered that the amorphous silicon (a-Si:H) has Stabler-Wronski effect. That is to say, the hydrogenated amorphous silicon (a-Si:H) has a fatal defect of being seriously degraded by light irradiation.

Therefore, many efforts have been made to reduce the Stabler-Wronski effect of amorphous silicon materials. As a result, methods for performing hydrogen (H₂) dilution on SiH₄ were developed.

In addition, researches are now being devoted to a thin film silicon solar cell capable of reducing the light-induced degradation and improving the efficiency by enhancing an internal reflection of light. Through the use of an n-layer having a low refractive index, the light trapping effect is maximized by reflecting light in a long wavelength range. As a result, a reduced thickness of hydrogenated amorphous silicon (a-Si:H) light absorber or hydrogenated microcrystalline silicon (μc-Si:H) light absorber as well as a high short circuit current is obtained. Thus, light-induced degradation ratio is decreased and a throughput is improved, and therefore a manufacturing cost is reduced.

Also, the abrupt hetero-junction or weak electric field at an n/i interface brings about the recombination of photo-generated carries and degrades the efficiency. Therefore, it is necessary to achieve a high efficiency through the improvement of long wavelength responses by reducing the recombination at the n/i interface.

In the mean time, a single-junction thin film silicon solar cell has its own limited attainable performance. Accordingly, a double-junction thin film silicon solar cell or a triple-junction thin film silicon solar cell, each of which has a plurality of stacked unit cells, has been developed, and thereby pursuing a high stabilized efficiency after light irradiation.

### SUMMARY OF THE INVENTION

One aspect of the present invention is a thin film silicon solar cell including: a substrate: a first electrode which is stacked on the substrate; a unit cell which is stacked on the first electrode; and a second electrode which is stacked on the unit cell. The unit cell includes a p-type window layer, an i-type photoelectric conversion layer and an n-type layer. The n-type layer includes an n-type silicon alloy reflector profiled such that a concentration of a refractive index reduction element is increased or decreased with the increase in a distance from a light incident side.

Another aspect of the present invention is a thin film silicon solar cell including: a substrate; a first electrode which is stacked on the substrate; a unit cell which is stacked on the first electrode; and a second electrode which is stacked on the unit cell. The unit cell includes a p-type window layer, an i-type photoelectric conversion layer and an n-type layer. The n-type layer includes an n-type silicon alloy reflector in which a first sub-layer having a relatively low refractive index reduction element content and a second sub-layer having a relatively high refractive index reduction element content are alternately stacked.

### BRIEF DESCRIPTION OF THE DRAWINGS

FIG. 1 is a cross sectional view showing a p-i-n type single-junction thin film silicon solar cell according to a first embodiment of the present invention;

FIG. 2 is a cross sectional view showing a profiled n-type silicon alloy reflector according to an embodiment included in the p-i-n type single-junction thin film silicon solar cell of FIG. 1;

FIG. 3 is a cross sectional view showing a profiled n-type silicon alloy reflector according to another embodiment included in the p-i-n type single-junction thin film silicon solar cell of FIG. 1;

FIG. 4 is a graph showing a photo current density-voltage curve depending on the structure of a profiled n-type silicon alloy reflector of a p-i-n type single-junction amorphous silicon solar cell according to the embodiment of the present invention;

FIG. 5 is a graph showing external quantum efficiency spectra depending on the structure of a profiled n-type silicon alloy reflector of a p-i-n type single-junction amorphous silicon solar cell according to the embodiment of the present invention;

FIG. 6 is a graph for describing a process of obtaining a crystal volume fraction by Raman analysis;

FIG. 7 is a graph showing Raman analysis of the profiled n-type silicon alloy reflector and an n-type layer of the single-junction thin film silicon solar cell in accordance with the embodiment of the present invention;

FIG. 8 is a cross sectional view showing in detail a unit cell including the profiled n-type silicon alloy reflector according to the embodiment of the present invention;

FIG. 9 is a cross sectional view showing a p-i-n type multi-junction thin film silicon solar cell according to a second embodiment of the present invention;

FIG. 10 is a cross sectional view showing in detail a unit cell including the profiled n-type silicon alloy reflector according to the embodiment of the present invention;

FIG. 11 is a cross sectional view showing an n-i-p type single-junction thin film silicon solar cell according to a third embodiment of the present invention;

FIG. 12 is a cross sectional view showing in detail a unit cell including the profiled n-type silicon alloy reflector according to the embodiment of the present invention;

FIG. 13 is a cross sectional view showing an n-i-p type multi-junction thin film silicon solar cell according to a fourth embodiment of the present invention;

FIG. 14 is a flowchart showing a manufacturing method of the amorphous silicon solar cell according to the embodiment of the present invention;

FIG. 15 is a flowchart showing a profile method according to the embodiment of the present invention; and

FIG. 16 is a flowchart showing in detail the profile method according to the embodiment of the present invention.

### DETAILED DESCRIPTION OF THE DRAWINGS

FIG. 1 is a cross sectional view showing a p-i-n type single-junction thin film silicon solar cell according to an embodiment of the present invention.

As shown in FIG. 1, the p-i-n type single-junction thin film silicon solar cell according to an embodiment of the present invention includes a front transparent electrode 20 stacked on a substrate 10, a unit cell 30 stacked on the front transparent electrode 20, and a back electrode 40 stacked on the unit cell 30.

Referring to FIG. 1, the substrate 10 according to the embodiment of the present invention may be a transparent insulating substrate. The substrate 10 may be a flexible substrate such as metal foil or polymer or may be an inflexible substrate such as glass. The substrate may include a surface unevenness having a pitch of 100 nm to 900 nm.

The transparent electrode 20 may be formed of a transparent conductive oxide such as ZnO, SnO₂ and IZO. When transparent conductive oxide is formed by chemical vapor deposition (CVD), the unevenness may be formed on the surface of the transparent conductive oxide. The surface unevenness of the transparent conductive oxide improves the light trapping effect.

Referring to FIG. 1, the unit cell 30 includes an amorphous silicon p-type window layer 31 stacked on the front transparent electrode 20, an i-type photoelectric conversion layer 32 stacked on the p-type window layer 31, and an n-type layer 33 stacked on the i-type photoelectric conversion layer 32. Sunlight is absorbed by the p-i-n junction i-type photoelectric conversion layer 32. The absorbed sunlight is converted into electron-hole pairs. The photo-generated electron-hole pairs traverse the i-type photoelectric conversion layer 32. An electric field formed between the p-type window layer 31 and the n-type layer 33 causes the electrons to move to the n-type layer 33 and causes the electron-holes to move to the p-type window layer 31, and thereby generating a current.

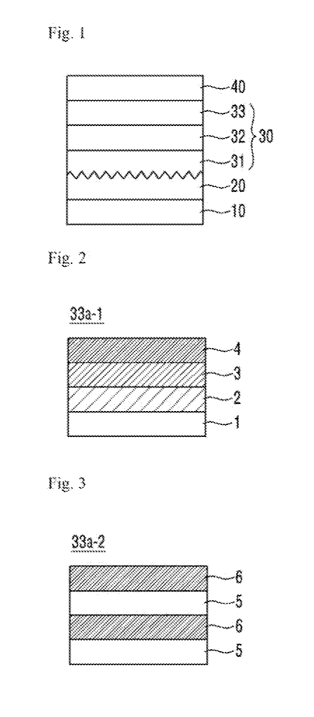

FIGS. 2 and 3 are cross sectional views of two types 33a-1 and 33a-2 of an n-type silicon alloy reflector 33a according to the embodiment of the present invention.

In order to enhance an internal reflection of the n-type layer 33, the n-type layer 33 according to the embodiment of the present invention may be formed of the n-type silicon alloy reflector 33a profiled with a refractive index reduction element.

According to the embodiment of the present invention, the n-type silicon alloy reflector 33a may be profiled with the refractive index reduction element as described below. Hereafter, two profile methods will be described. However, this is only an example and it is clear that the n-type silicon alloy reflector 33a can be profiled by other methods.

First, the n-type silicon alloy reflector 33a-1 may be profiled such that the refractive index reduction element content is increased or decreased gradually or stepwisely in the n-type silicon alloy reflector 33a-1.

Accordingly, the refractive index within the n-type silicon alloy reflector 33a-1 may be decreased or increased gradually or stepwisely with the increase in a distance from a light incident side.

The internal reflection of the n-type layer 33 is enhanced using the n-type silicon alloy reflector 33a-1 as the n-type layer 33. Therefore, the light utilization efficiency of the i-type photoelectric conversion layer 32 can be improved.

FIG. 2 is a cross sectional view of an embodiment of the n-type silicon alloy reflector 33a-1 profiled by the first method.

FIG. 2 shows that the n-type silicon alloy reflector 33a-1 is formed such that the refractive index reduction element is increased in a step manner depending on the thickness of the n-type silicon alloy reflector 33a-1. For example, when the n-type silicon alloy reflector 33a-1 of FIG. 2 is formed, a flow rate ratio of SiH₄ to CO₂ is intended to be 0, 0.4, 0.8 and 1.2, and thus a plurality of layers 1, 2, 3 and 4 are formed. Here, it is shown that the thickness of the layers 1, 2, 3 and 4 has an identical value of 7.5 nm.

The n-type silicon alloy reflector 33a-1 is formed in such a manner, and thus the internal reflection within the n-type silicon alloy reflector 33a-1 may be increased. In the i-type photoelectric conversion layer 32 having a constant thickness, when the n-type silicon alloy reflector 33a-1 is used as the n-type layer 33, photovoltaic conversion efficiency of the i-type photoelectric conversion layer 32 may be higher than that of a case where the n-type silicon alloy reflector 33a-1 is not used as the n-type layer 33. The refractive index reduction element content of the n-type silicon alloy reflector 33a-1 is not necessarily increased or decreased in a step manner and may be continuously increased or decreased.

Secondly, the n-type silicon alloy reflector 33a-2 may be formed by alternately stacking a first sub-layer 5 and a second sub-layer 6, both of which have different refractive index reduction element contents from each other.

The first sub-layer 5 having the low refractive index reduction element content is stacked close to a light incident side, and the second sub-layer 6 is stacked farther from the light incident side. Subsequently, the first sub-layer 5 and the second sub-layer 6 are alternately stacked. This is shown in FIG. 3. As such, when the two layer having mutually different refractive indices are alternately stacked, internal reflection is caused at each interface formed by the stack of the layers. As a result, multiple reflections are formed within the n-type silicon alloy reflector 33a-2.

FIG. 3 shows that the first sub-layer having a low refractive index reduction element content and the second sub-layer having relatively high refractive index reduction element content are alternately stacked twice and the n-type silicon alloy reflector 33a-2 is formed. For example, when the first sub-layer 5 and the second sub-layer 6 of FIG. 3 are formed, a flow rate ratio of SiH₄ to CO₂ is intended to be 0 and 1.2 respectively, so that the n-type silicon alloy reflector 33a-2 are formed.

FIG. 3 shows that the thickness of each of the layers 5 and 6 is 7.5 nm. The thicknesses of the layers 5 of the pairs of the layers 5 and 6 are the same as each other. The thicknesses of the layers 6 of the pairs of the layers 5 and 6 are the same as each other. FIG. 3 also shows that the refractive index reduction element contents of the layers 5 of the pairs of the layers 5 and 6 are the same as each other. The refractive index reduction element contents of the layers 6 of the pairs of the layers 5 and 6 are the same as each other. However, there is no limit to this. Two layers having mutually different refractive indices may be alternately stacked. Also, the thicknesses of the layers 5 are not necessarily the same as each other and the thicknesses of the layers 6 are not necessarily the same as each other. Also, the refractive index reduction element contents of the layers 5 are not necessarily the same as each other and the refractive index reduction element contents of the layers 6 are not necessarily the same as each other.

Although FIG. 3 shows that the first sub-layer 5 and the second sub-layer 6 are alternately stacked twice, this is only an example. The first sub-layer 5 and the second sub-layer 6 may be alternately stacked from one time to four times. The internal reflection enhancement effect is increased with the increase in the refractive index difference between adjacent sub-layers. Also, the internal reflection enhancement effect is increased with the increase in the number of the stacking of the sub-layers.

The higher the electric conductivity of the first sub-layer 5 which is placed closest to the i-type photoelectric conversion layer 32 is, the more the fill factor of the solar cell can be improved. Therefore, the refractive index reduction element content of the first sub-layer 5 may be low. Therefore, in the embodiment of the present invention, a flow rate ratio of CO₂/SiH₄ may be 0 at the time of forming the first sub-layer 5. An average content of the refractive index reduction element in the first sub-layer 5 may be equal to or more than O atomic % and equal to or less than 20 atomic %. An average content of the refractive index reduction element in the second sub-layer 6 may be equal to or more than 20 atomic % and equal to or less than 50 atomic %. The refractive index reduction element may include carbon, nitrogen, oxygen and the like.

When the average content of the refractive index reduction element of the first sub-layer 5 is equal to or less than 20 atomic %, the electric conductivity of the first sub-layer 5 can be prevented from being reduced and the fill factor can be hereby prevented from being reduced. When the average content of the refractive index reduction element of the second sub-layer 6 is equal to or more than 20 atomic %, the refractive index of the second sub-layer 6 is reduced and an effective internal reflection is hereby easily formed. When the average content of the refractive index reduction element is unnecessarily large, the vertical electric conductivity of the second sub-layer 6 may be reduced.

Accordingly, in the embodiment of the present invention, when the average content of the refractive index reduction element in the first sub-layer 5 is equal to or more than O atomic % and equal to or less than 20 atomic % and the average content of the refractive index reduction element in the second sub-layer 6 is equal to or more than 20 atomic % and equal to or less than 50 atomic %, the electric conductivity of the n-type silicon alloy reflector 33a-2 is adequately maintained, and thus the fill factor and open circuit voltage of the solar cell can be prevented from being reduced.

The thicknesses of the first and second sub-layers 5 and 6 are equal to or larger than 2.5 nm and equal to or less than 10 nm. When the thicknesses of the first and second sub-layers 5 and 6 are less than 2.5 nm, the electric conductivity is low, and thereby a strong electric field cannot be formed in the i-type photoelectric conversion layer 32. As a result, the open circuit voltage may become lower. When the thicknesses of the first and second sub-layers 5 and 6 are larger than 10 nm, the light absorption in the first sub-layer 5 is increased and the short circuit current is decreased. Also, the series resistance is increased and the fill factor is reduced. As a result, conversion efficiency may be reduced.

Up to now, as described with reference to FIGS. 2 and 3, the total thickness of the n-type silicon alloy reflector 33a profiled with the refractive index reduction element may be equal to or larger than 20 nm and equal to or less than 80 nm. When the thickness of the profiled n-type silicon alloy reflector 33a is less than 20 nm, the electric conductivity is low, and thereby a strong electric field cannot be formed in the i-type photoelectric conversion layer 32. As a result, the open circuit voltage is decreased. When the thickness of the profiled n-type silicon alloy reflector 33a is larger than 80 nm, the light absorption in the profiled n-type silicon alloy reflector 33a is increased and the short circuit current is decreased. Also, the fill factor is reduced by the increase in the serial resistance, and thus the conversion efficiency is reduced.

The average content of the refractive index reduction element in the profiled n-type silicon alloy reflector 33a may be equal to or more than 10 atomic % and equal to or less than 50 atomic %. The refractive index reduction element may include carbon, nitrogen, oxygen and the like. When the average content of the refractive index reduction element is equal to or more than 10 atomic %, the refractive index of the profiled n-type silicon alloy reflector 33a is reduced and the effective internal reflection is easily formed.

When the average content of the refractive index reduction element is unnecessarily large, the vertical electric conductivity in the vertical direction of the profiled n-type silicon alloy reflector 33a may be reduced. Therefore, in the embodiment of the present invention, when the average content of the refractive index reduction element is equal to or less than 50 atomic %, the electric conductivity of the profiled n-type silicon alloy reflector 33a is adequately maintained, and thus the fill factor and open circuit voltage of the solar cell can be prevented from being reduced.

Through the use of the profiled n-type silicon alloy reflector 33a according to the embodiment of the present invention, the internal reflection is increased and the short circuit current of the thin film solar cell is increased, and thus the conversion efficiency may be improved.

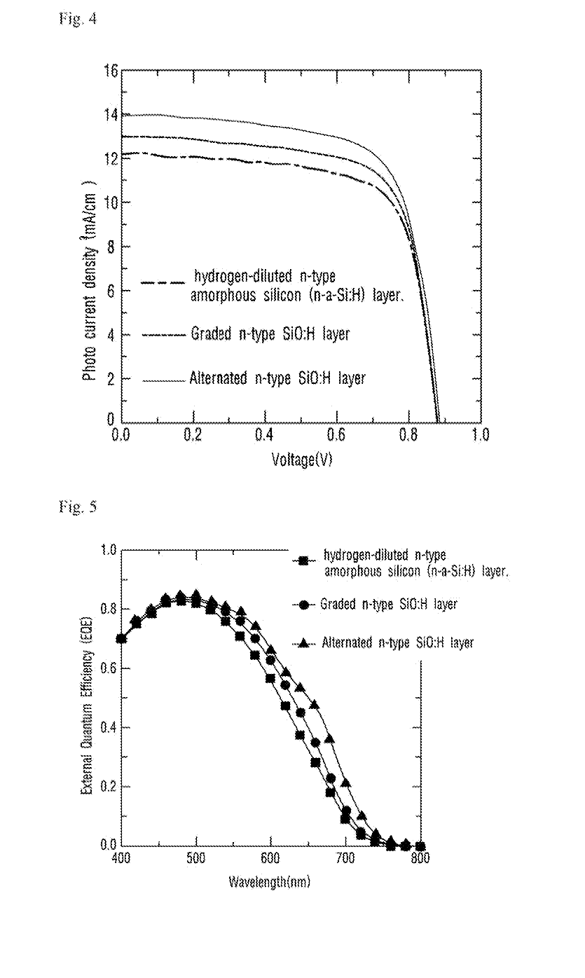

FIG. 4 is a graph showing a photo current density-voltage curve of the single-junction amorphous silicon solar cell according to the embodiment of the present invention. Here, an hydrogenated intrinsic amorphous silicon (i-a-Si:H) light absorber is considerably thin. In other words, the thickness of the hydrogenated intrinsic amorphous silicon (i-a-Si:H) light absorber is 160 nm.

FIG. 5 is a graph showing external quantum efficiency spectra of the single-junction amorphous silicon solar cells according to the embodiment of the present invention.

Referring to FIG. 4, it can be found that when the profiled n-type silicon alloy reflector 33a according to the embodiment of the present invention is used as the n-type layer 33, the short circuit current is greater than the short circuit current of a solar cell including highly hydrogen-diluted n-type amorphous silicon (n-a-Si:H) layer.

Referring to FIG. 5, it can be found that when the profiled n-type silicon alloy reflector 33a according to the embodiment of the present invention is used as the n-type layer 33, the external quantum efficiency is higher in a long wavelength region of visible light than the external quantum efficiency of the solar cell including the highly hydrogen-diluted n-type amorphous silicon (n-a-Si:H) layer.

The performances of the single-junction amorphous silicon solar cell according to the structure of the n-type layer are shown in Table 1.

TABLE 1

| | open circuit | short circuit | | |
|---|---|---|---|---|
| | voltage | current | fill factor | efficiency |
| n-type layer structure | Voc (V) | Jsc (mA/cm²) | (FF) | Eff (%) |
| highly hydrogen-diluted n-type | 0.876 | 12.1 | 0.709 | 7.52 |
| amorphous silicon layer (30 nm) | | | | |
| n-type silicon oxide layer (30 nm) in | 0.874 | 12.9 | 0.711 | 8.03 |
| which an oxygen content is | | | | |
| increased stepwisely | | | | |
| n-type silicon oxide layer (30 nm) in | 0.883 | 13.9 | 0.698 | 8.58 |
| which two layers having mutually | | | | |
| different oxygen contents are | | | | |
| alternately stacked | | | | |
| n-type silicon oxide layer (30 nm) in | 0.881 | 14.0 | 0.695 | 8.59 |
| which an oxygen content is | | | | |
| increased stepwisely/zinc oxide | | | | |
| layer (50 nm) | | | | |

Referring to FIGS. 4 and 5, and Table 1, the quantum efficiency in the long wavelength region of visible light and the short circuit current of the thin film solar cell including the n-type silicon alloy reflector 33a which is profiled with a refractive index reduction element of oxygen are more excellent than those of the amorphous silicon solar cell including the highly hydrogen-diluted n-type amorphous silicon (n-a-Si:H) layer. This is because the active internal reflection caused by the refractive index reduction is formed in the profiled n-type silicon alloy reflector 33a, and thus the short circuit current with the n-type silicon alloy reflector 33a becomes greater than that with the highly hydrogen-diluted n-type amorphous silicon (n-a-Si:H) layer.

Since the internal reflection is enhanced through the use of the profiled n-type silicon alloy reflector 33a according to the embodiment of the present invention, it is possible to obtain the comparable conversion efficiency even using the thinner light absorber, i.e., the i-type photoelectric conversion layer 32. There is a problem that the degradation ratio of the i-type photoelectric conversion layer 32 caused by light irradiation is increased with the increase in the thickness of the i-type photoelectric conversion layer 32. Therefore, when the profiled n-type silicon alloy reflector 33a according to the embodiment of the present invention is used as the n-type layer 33, the light utilization efficiency is improved and the thickness of the i-type photoelectric conversion layer 32 is reduced, and thus the degradation ratio can be decreased. Moreover, the throughput and manufacturing cost may be also reduced. A back reflector is generally used between the unit cell 30 and the back electrode 40 in order to enhance the light trapping effect by reflecting light. In general, zinc oxide (ZnO) having a refractive index of about 2.0 is used as the back reflector.

However, according to the present invention, the internal reflection is enhanced using the profiled n-type silicon alloy reflector 33a, and thus the light trapping effect is improved. Therefore, through the embodiment of the present invention, it is possible to obtain the same conversion efficiency without using the ZnO back reflector. In other words, the profiled n-type silicon alloy reflector 33a according to the embodiment of the present invention can be substituted for the back reflector. The optimum thickness of the ZnO back reflector may be reduced using the n-type silicon alloy reflector 33a. Therefore, the amount of the expensive zinc (Zn) generally used to form the back reflector may be decreased. As a result, a manufacturing cost may be reduced. According to the embodiment, the thickness of the back reflector formed of the zinc oxide may be decreased to 5 nm or less, or the back reflector may be omitted.

The profiled n-type silicon alloy reflector 33a according to the embodiment of the present invention has an more excellent adhesion to the back electrode 40 than that of the hydrogenated n-type amorphous silicon layer or an hydrogenated n-type microcrystalline silicon layer, each of which is conventionally generally used as an n-type layer. In particular, a conventional hydrogenated n-type amorphous silicon layer or hydrogenated n-type microcrystalline silicon layer has a very poor adhesion to the back electrode 40 formed of silver (Ag). However, the profiled n-type silicon alloy reflector 33a generates actively an oxide film and has a good adhesion to the back electrode 40. Therefore, production yield can be improved during mass production of solar modules.

An average impurity concentration of the profiled n-type silicon alloy reflector 33a may be equal to or higher than 1×10¹⁹/cm³ and equal to or less than 1×10¹⁹ cm³. When the average impurity concentration is less than 1×10¹⁹/cm³, the electrical conductivity becomes lower, and the open circuit voltage and the fill factor (FF) are reduced. When the average impurity concentration is higher than 1×10²¹/cm³, the light absorption increases and the short circuit current is reduced. Phosphorus (P) may be used as n-type doping impurity for the deposition of the profiled n-type silicon alloy reflector 33a.

An average hydrogen content of the profiled n-type silicon alloy reflector 33a may be equal to or more than 5 atomic % and equal to or less than 25 atomic %. When the average hydrogen content is less than 5 atomic %, a defect density of the n layer becomes higher, and thus the recombination is increased. When the average hydrogen content is more than 25 atomic % microvoids within the thin film are increased and the n layer becomes porous, and thus the recombination is increased.

The back electrode 40 functions as a back electrode of the unit cell as well as reflects light which has transmitted through the solar cell layer. The back electrode 40 may be formed of metal oxide such as ZnO, ITO, SnO₂ and the like or a metallic material such as Ag, Al and the like by CVD or sputtering.

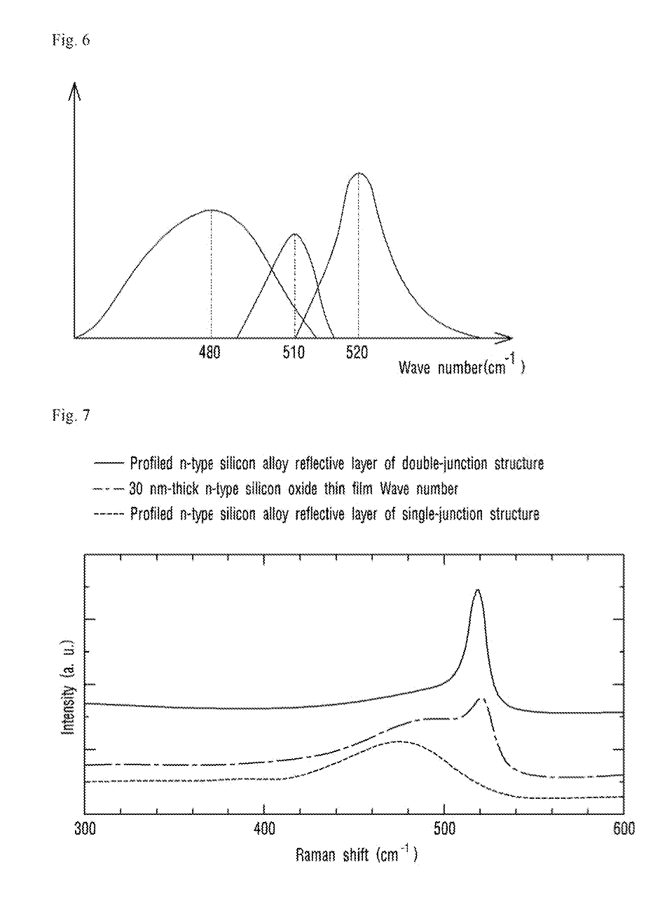

FIG. 6 is a graph for describing a process of calculating a crystal volume fraction.

The crystal volume fraction is obtained by the following equation.

crystal volume fraction(%)=[(A₅₁₀+A₅₂₀)/(A₄₈₀+A₅₁₀+A₅₂₀)]*100

Here, Aᵢ is an area of a component peak in the vicinity of i cm⁻¹.

For example, three peaks shown in FIG. 4 are obtained by performing Raman spectroscopy on any layer of the solar cell. The area of component peak in the vicinity of 480 cm⁻¹ obtained by means of Gaussian peak fitting corresponding to the amorphous silicon TO mode. The area of component peak in the vicinity of 510 cm⁻¹ is obtained by means of Gaussian peak fitting corresponding to a small grain or grain boundary defect. The area of component peak in the vicinity of 520 cm⁻¹ obtained by means of Gaussian peak fitting corresponding to the crystalline silicon TO mode.

FIG. 7 is a graph showing a measurement result of Raman spectroscopy by irradiating HeNe laser with a wavelength of 633 nm to the back side of the n-type layer of the thin film solar cell according to the present invention. As shown in FIG. 7, a 30 nm-thick n-type silicon oxide thin film which is formed on a glass substrate and in which the oxygen content is decreased by stepwisely has a phase of the microcrystalline silicon having a crystal volume fraction of about 36%. However, the Raman spectrum measured from the n layer of the back side of the single-junction amorphous silicon solar cell does not show any peak related to a crystalline silicon grain near 510 cm⁻¹ or 520 cm⁻¹ and show only a peak related to a crystalline silicon grain near 480 cm⁻¹, and thus a complete amorphous silicon phase having a crystal volume fraction almost close to 0% is shown. This is because the i-type photoelectric conversion layer 32 prevents the crystallization of an n-type silicon oxide reflector 33a-1.

When the Raman spectrum is measured by irradiating laser with a wavelength of 633 nm to the back side of the single-junction amorphous silicon solar cell, the crystal volume fraction may be equal to or greater than 0% and equal to or less than 25%. The greater the crystal volume fraction is, the more the resistance increase caused by amorphization of the profiled n-type silicon alloy reflector 33a is prevented. When the crystal volume fraction of the profiled n-type silicon alloy reflector 33a is designed to be greater than 25%, it is required that a hydrogen dilution ratio of the profiled n-type silicon alloy reflector 33a should be very high or the thickness of the profiled n-type silicon alloy reflector 33a should be very thick. Therefore, the manufacturing cost may rise or the short circuit current may be reduced by the increase in light absorption of the profiled n-type silicon alloy reflector 33a.

According to the embodiment of the present invention, a hydrogen-diluted n-type amorphous silicon layer 33b which is more slightly hydrogen-diluted than the profiled n-type silicon alloy reflector 33a may be included between the i-type photoelectric conversion layer 32 and the profiled n-type silicon alloy reflector 33a. This is shown in FIG. 8.

FIG. 8 is a cross sectional view showing in detail the unit cell including the n-type layer according to the embodiment of the present invention.

When oxygen in the air diffuses to the i-type photoelectric conversion layer 32, the i-type photoelectric conversion layer 32 is changed into the weakly n-type layer because oxygen acts as a shallow donor. The n-type amorphous silicon layer has a high resistance to the diffusion of oxygen in the air into the solar cell.

When the n-type layer is comprised of only the highly hydrogen-diluted profiled n-type silicon alloy reflector 33a, the high open circuit voltage is obtained due to the high electrical conductivity. However, interface properties are deteriorated at the n/i interface due to the sudden change of Fermi level. That is, the high recombination of photo-generated carriers at the n/i interface causes the till factor (FF) to be remarkably reduced. When the slightly hydrogen-diluted n-type amorphous silicon (n-a-Si:H) layer 33b is even thinly interposed between the profiled n-type silicon alloy reflector 33a and the i-type photoelectric conversion layer 32, the recombination is considerably decreased at the n/i interface. As a result, the fill factor (FE) is prevented from being reduced, and the open circuit voltage and short circuit current are maintained higher. Consequently, the efficiency is enhanced.

The thickness of the slightly hydrogen-diluted n-type amorphous silicon layer 33b should be 3 nm to 7 nm. When the thickness of the slightly hydrogen-diluted n-type amorphous silicon layer 33b is equal to or larger than 3 nm, the slightly hydrogen-diluted n-type amorphous silicon layer 33b is capable of correctly functioning to reduce the recombination at the n/i interface. When the thickness of the slightly hydrogen-diluted n-type amorphous silicon layer 33b is equal to or smaller than 7 nm, the light absorption in the slightly hydrogen-diluted n-type amorphous silicon layer is increased and short circuit current can be prevented from being decreased. Also, the fill factor is reduced by the increase in the serial resistance, and thus the conversion efficiency is prevented from being reduced.

Meanwhile, no matter how much degradation by light irradiation is reduced, there is a limit to the efficiency of the single-junction thin film silicon solar cell. Thus, high stabilized efficiency can be obtained by constructing either a double-junction thin film silicon solar cell formed by stacking a top cell based on the amorphous silicon and a bottom cell based on the microcrystalline silicon or a triple-junction thin film silicon solar cell formed by further developing the double-junction solar cell.

The open circuit voltage of the double-junction solar cell or the triple-junction solar cell is a sum of the open circuit voltages of all of unit cells. The short circuit current of the double-junction solar cell or the triple-junction solar cell is a minimum value among the short circuit currents of all of the unit cells. In manufacturing a multi-junction solar cell, an optical band gap of the intrinsic light absorber becomes narrower toward to the bottom cell from the light incident top cell by using hetero-junction between the unit cells. The light of broad spectrum is absorbed by separating the spectrum of light absorbed by each cell, and thus the light utilization efficiency is improved. Additionally, since the intrinsic light absorber of the top cell based on the amorphous silicon which is severely degraded by light irradiation becomes thinner, a degradation ratio is reduced and a high stabilized efficiency can be obtained.

Therefore, next, a multi-junction thin film silicon solar cell according to a second embodiment of the present invention will be described.

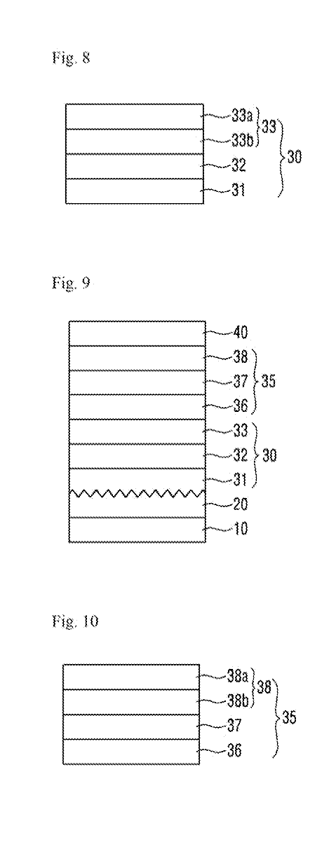

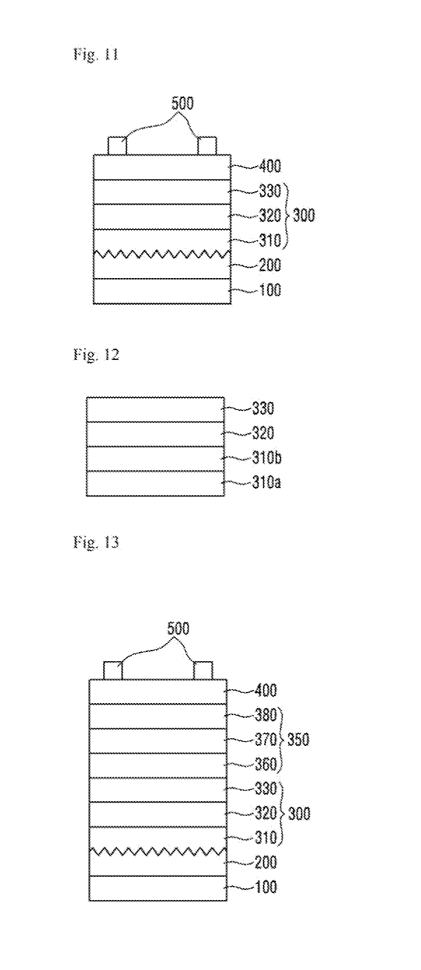

FIG. 9 is a cross sectional view showing a p-i-n type multi-junction thin film silicon solar cell according to a second embodiment of the present invention. FIG. 10 is a cross sectional view showing in detail the bottom cell of the p-i-n type multi-junction thin film silicon solar cell shown in FIG. 9.

Although FIG. 9 shows the double-junction thin film silicon solar cell, triple or more than triple-junction thin film silicon solar cell can be provided. Those skilled in the art can easily change designs of these solar cells. For convenience of description, the double-junction solar cell will be taken as an example for description in FIG. 9.

Referring to FIG. 9, the p-i-n type multi-junction thin film silicon solar cell according to the second embodiment of the present invention may be formed by adding at least one p-i-n type unit cell between the unit cell 30 and the back electrode 40 in the aforementioned p-i-n type single-junction thin film solar cell.

The added unit cell 35 corresponds to the bottom cell of the p-i-n type double-junction thin film solar cell and includes a p-type window layer 36 stacked on the unit cell 30 corresponding to the top cell, an i-type photoelectric conversion layer 37 and an n-type layer 38 stacked on the i-type photoelectric conversion layer 37.

Referring to FIGS. 9 and 10, the n-type layer 38 of the bottom cell 35 which is the farthest from a light incident side may include a profiled n-type silicon alloy reflector 38a. Through such a configuration, light which has not been absorbed in the top cell 30 and the bottom cell 35 is reflected by the profiled n-type silicon alloy reflector 38a, and then can be absorbed in the top cell 30 and the bottom cell 35. As a result, the photovoltaic conversion efficiency can be improved.

Also, as shown in FIG. 10, like the p-i-n type single-junction thin film silicon solar cell, a relatively slightly hydrogenated n-type amorphous silicon layer 38b may be formed between the profiled n-type silicon alloy reflector 38a and the i-type photoelectric conversion layer 37.

A method for profiling the silicon alloy reflector 38 of the bottom cell 35 is the same as the aforementioned method for profiling the n-type layer of the p-i-n type single-junction thin film solar cell.

As shown in FIG. 5, when the thin film silicon solar cell has the double-junction structure, by Raman spectroscopy, a crystal volume fraction measured from the n-type layer 38 of the back side of the double-junction solar cell is 60%. Since laser with a wavelength of 633 nm transmits through the n-type layer 38 of the bottom cell 35 and reaches the i-type microcrystalline silicon photoelectric conversion layer 37 of the bottom cell 35, the double-junction solar cell has a crystal volume fraction greater than that of the single-junction solar cell. It is preferable that the crystal volume fraction should be 30% to 85%. If the crystal volume fraction is less than 30%, an amorphous incubation layer is formed in the i-type photoelectric conversion layer 37 of the bottom cell 35, and hence the long wavelength characteristics of the solar cell is deteriorated. If the crystal volume fraction is greater than 85%, the grain boundary volume of the i-type photoelectric conversion layer 37 of the bottom cell 35 grows and the recombination of the photo-generated carriers is increased.

According to the embodiment of the present invention, in the p-i-n type double-junction thin film solar cell, the n-type layer 33 of the top cell 30 may not necessarily include the profiled n-type silicon alloy reflector. Additionally, although not shown in FIG. 9, an intermediate reflector causing the internal reflection may be formed between the top cell 30 and the bottom cell 35.

The n-type silicon alloy reflector 38a according to the embodiment of the present invention may be applied to not only the p-i-n type single-junction thin film silicon solar cell but also the double-junction or triple or more than triple-junction structure. The n-type silicon alloy reflector 38a increases the efficiency of the solar cell.

The triple-junction structure may be formed by further including a third unit cell (not shown) between the top cell 30 and the bottom cell 35.

Like the top cell 30, the n-type layer of the third unit cell may include the profiled n-type silicon alloy reflector.

FIG. 11 is a cross sectional view showing an n-i-p type single-junction thin film silicon solar cell according to a third embodiment of the present invention. FIG. 12 is a cross sectional view showing in detail a unit cell including the n-type layer according to the embodiment of the present invention.

Referring to FIG. 11, the n-i-p type single-junction thin film silicon solar cell according to the embodiment of the present invention includes a back electrode 200 stacked on a substrate 100, a unit cell 300 stacked on the back electrode 200, and a front transparent electrode 400 stacked on the unit cell 300.

The unit cell 300 of the n-i-p type thin film silicon solar cell includes an n-type layer 310 stacked on the back electrode 200, an i-type photoelectric conversion layer 320 stacked on the n-type layer 310, and a p-type window layer 330 stacked on the i-type photoelectric conversion layer 320.

The n-type layer 310 includes a profiled n-type silicon alloy reflector 310a. A method for profiling the n-type silicon alloy reflector 310a is the same as the aforementioned profiling method of the p-i-n type thin film solar cell. That is, as a first method, the refractive index of the profiled n-type silicon alloy reflector 310a may be increased or decreased gradually or stepwisely with the increase in a distance from a light incident side.

As a second method, the n-type silicon alloy reflector 310a may be formed by alternately stacking a first sub-layer and a second sub-layer, both of which have different refractive index reduction element contents from each other. The first sub-layer is formed close to a sunlight incident side. The refractive index reduction element content of the first sub-layer is low. The refractive index reduction element content of the second sub-layer is relatively high. When the two layer having mutually different refractive indices are alternately stacked, the multiple internal reflection can be caused. Therefore, the greater the number of the alternate sub-layer stacks is or the greater the refractive index difference between adjacent sub-layers is, the more the internal reflection is effectively increased.

The n-i-p type thin film silicon solar cell may further include a metal grid 500 on the front transparent electrode 400. The electric conductivity of the front transparent electrode 400 is helped by the metal grid 500, and thus the collection efficiency may be improved.

Also, the thickness of the front transparent electrode 400 may be decreased. Through the use of the profiled n-type silicon alloy reflector in the n-i-p type thin film silicon solar cell, a micro crack is more prevented from being formed in the i-type photoelectric conversion layer 320, for example, a hydrogenated i-type microcrystalline silicon layer, compared to the use of a conventional n-type amorphous silicon layer or a conventional n-type microcrystalline silicon layer, and thus the open circuit voltage and fill factor are improved. In particular, when the substrate is a flexible substrate, the formation of the micro crack is increased due to the bending or scratch of the substrate.

Referring to FIG. 12, like the p-i-n type thin film silicon solar cell, a relatively slightly hydrogenated n-type amorphous silicon layer 310b may be formed between the profiled n-type silicon alloy reflector 310a and the i-type photoelectric conversion layer 320. Since the structure and the effect of the relatively slightly hydrogenated n-type amorphous silicon layer 310b are the same as those of the p-i-n type thin film silicon solar cell, detailed descriptions thereof will be omitted in the following description.

FIG. 13 shows an n-i-p type multi-junction thin film silicon solar cell according to a fourth embodiment of the present invention. In other words, like the p-i-n type thin film solar cell, the n-type silicon alloy reflector 310a according to the embodiment of the present invention can be applied to a multi-junction solar cell in which a plurality of the unit cells are stacked. While FIG. 13 shows that two unit cells are stacked, the n-type silicon alloy reflector 310a can be applied to a triple-junction solar cell in which three unit cells are stacked.

As shown in FIG. 13, the profiled n-type silicon alloy reflector according to the embodiment of the present invention is included in the n-type layer of a unit cell which is the farthest from a light incident side among a plurality of the unit cells, and thus the light utilization efficiency of the multi-junction solar cell can be improved.

Next, a manufacturing method of a thin film silicon solar cell according to the embodiment of the present invention will be described.

FIG. 14 is a flowchart showing a manufacturing method of the p-i-n type thin film silicon solar cell according to the embodiment of the present invention.

As shown in FIG. 14, in the manufacture of the thin film silicon solar cell according to the present invention, the front transparent electrode is formed on an insulating substrate such as transparent glass or flexible polymer (S10). The front transparent electrode has a surface unevenness in order to improve the light trapping effect and is coated with a ZnO thin film or a SnO₂ thin film.

In the production of the thin film silicon solar cell, patterning is performed by a laser scribing method and the like for serial connection between the unit cells. A cleaning process is performed in order to remove particles generated during the patterning process and then the substrate is loaded in a vacuum chamber of a plasma-CVD system. Subsequently, residual moisture in the substrate is removed by a preheating process.

After the preheating process, the p-type window layer is stacked (S20).

After the substrate is carried to a p-layer deposition chamber, the pressure of the p-layer deposition chamber reaches a base pressure by the operation of a high vacuum pump like a turbo molecular pump.

After the pressure of the p-layer deposition chamber reaches the base pressure, reaction gas is introduced into the deposition chamber and the pressure of the deposition chamber reaches a deposition pressure by the introduction of the reaction gas. The reaction gas includes silane (SiH₄), hydrogen (H₂) and group III impurity gas. The group III impurity gas may include diborare gas (B₂H₆, TMB (TriMethylBoron), TEB (TriEthylBoron) and the like. The flow rate of each source gas is controlled by each mass flow controller (MFC).

When the pressure of the deposition chamber reaches a predetermined deposition pressure, the pressure of the deposition chamber is maintained constant by a pressure controller, which is connected to the deposition chamber, and an angle valve. The deposition pressure is set to a value for obtaining the thickness uniformity, high quality characteristics and an appropriate deposition rate of the thin film. The deposition pressure may be equal to or greater than 0.4 Torr and equal to or less than 2.5 Torr. If the deposition pressure is less than 0.4 Torr, the thickness uniformity and deposition rate of the p-type window layer are reduced. If the deposition pressure is greater than 2.5 Torr, powder is produced at a plasma electrode within the deposition chamber or the amount of gas used is increased, and therefore the manufacturing cost is increased.

When the pressure within the deposition chamber is stabilized to the deposition pressure, the reaction gas within the deposition chamber is decomposed by means of either radio frequency plasma enhanced chemical vapor deposition (RF PECVD) using a frequency of 13.56 MHz or very high frequency plasma enhanced chemical vapor deposition (VHF PECVD) using a frequency greater than 13.56 MHz. As a result, the slightly hydrogen-diluted p-type window layer is deposited.

The thickness of the p-type window layer 30a is equal to or larger than 12 nm and equal to or less than 17 nm. If the thickness of the p-type window layer is less than 12 nm, conductivity becomes lower and a strong electric field cannot be formed in an intrinsic light absorber. Therefore, the open circuit voltage of the photovoltaic device is low. If the thickness of the p-type window layer is larger than 17 nm, the light absorption in the p-type window layer increases and the short circuit current may be reduced. Therefore, the conversion efficiency may be reduced. Since the composition of the reaction gas is maintained constant during the deposition, the hydrogen-diluted p-type window layer having a constant optical band gap is formed.

The dark conductivity of the p-type window layer according to the embodiment of the present invention may be about 1×10⁻⁶ S/cm, and the optical band gap of the p-type window layer may be about 2.0 eV. A silane concentration, i.e. an indicator of the hydrogen dilution ratio at the time of forming the p-type window layer may be equal to or greater than 4% and equal to or less than 10%. Here, the silane concentration is a ratio of a sum of the silane flow rate and the hydrogen flow rate to the silane flow rate.

The deposition of the p-type window layer is completed by turning off the power of plasma.

The i-type photoelectric conversion layer is stacked on the p-type window layer (S30). Various intrinsic light absorbers may be used as the i-type photoelectric conversion layer.

Here, in the p-i-n type amorphous silicon solar cell to which the profiled n-type silicon alloy reflector of the present invention is effectively applied, there are kinds of the intrinsic light absorber, such as hydrogenated intrinsic amorphous silicon (i-a-Si:H), hydrogenated intrinsic proto-crystalline silicon (i-pc-Si:H), hydrogenated intrinsic proto-crystalline silicon (i-pc-Si:H) multilayer, hydrogenated intrinsic amorphous silicon carbide (i-a-SiC:H), hydrogenated intrinsic proto-crystalline silicon carbide (i-pc-SiC:H), hydrogenated intrinsic proto-crystalline silicon carbide (i-pc-SiC:H) multilayer, hydrogenated intrinsic amorphous silicon oxide (i-a-SiO:H), hydrogenated intrinsic proto-crystalline silicon oxide (i-pc-SiO:H), hydrogenated intrinsic proto-crystalline silicon oxide (i-pc-SiO:H) multilayer and the like.

Regarding a p-i-n type double-junction solar cell, there are kinds of the intrinsic light absorber of the bottom cell, such as hydrogenated intrinsic amorphous silicon (i-a-Si:H), hydrogenated intrinsic amorphous silicon germanium (i-a-SiGe:H), hydrogenated intrinsic proto-crystalline silicon germanium (i-pc-SiGe:H), hydrogenated intrinsic nano-crystalline silicon (i-nc-Si:H), hydrogenated intrinsic microcrystalline silicon (i-μc-Si:H), hydrogenated intrinsic microcrystalline silicon gennanium (i-μc-SiGe:H) and the like.

Regarding a p-i-n type triple-junction solar cell, there are kinds of the intrinsic light absorber of a middle cell, such as hydrogenated intrinsic amorphous silicon germanium (i-a-SiGe:H), hydrogenated intrinsic proto-crystalline silicon germanium (i-pc-SiGe:H), hydrogenated intrinsic nano-crystalline silicon (i-nc-Si:H), hydrogenated intrinsic microcrystalline silicon (i-μc-SiH), hydrogenated intrinsic microcrystalline silicon germanium carbon (i-μc-SiGeC:H) and the like. There are kinds of the intrinsic light absorber of the bottom cell, such as hydrogenated intrinsic amorphous silicon germanium (i-a-SiGe:H), hydrogenated intrinsic proto-crystalline silicon germanium (i-pc-SiGe:H), hydrogenated intrinsic nano-crystalline silicon (i-nc-Si:H), hydrogenated intrinsic microcrystalline silicon (i-μc-Si:H), hydrogenated intrinsic microcrystalline silicon germanium (i-μc-SiGe:H) and the like.

Subsequently, the profiled n-type silicon alloy reflector is stacked on the i-type intrinsic light absorber (S40). Then, the back electrode is stacked on the profiled n-type silicon alloy reflector (S50). Thus, the thin film silicon solar cell is manufactured.

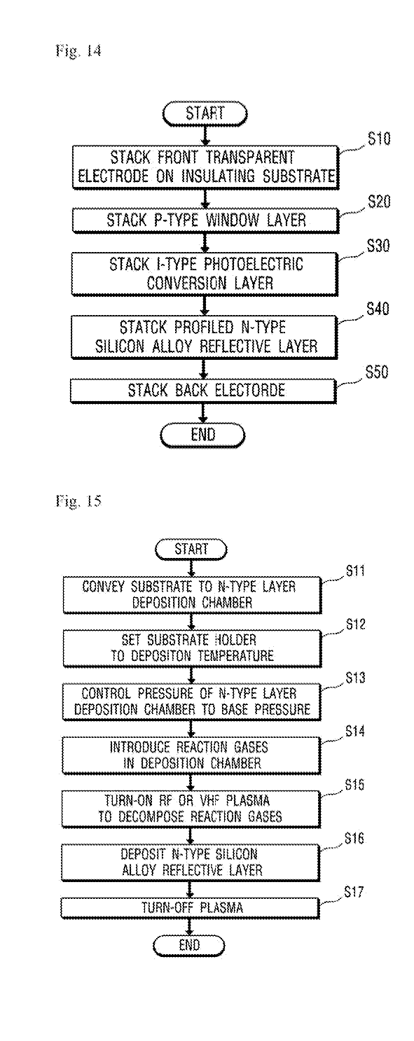

FIG. 15 is a flowchart showing a method of profiling the n-type silicon alloy reflector according to the embodiment of the present invention.

As shown in FIG. 15, a method for manufacturing the profiled n-type silicon alloy reflector which is deposited on the i-type photoelectric conversion layer is as follows.

First, the substrate on which the i-type photoelectric conversion layer has been stacked is transferred to an n-layer deposition chamber in order to deposit the n-type layer (S11).

Here, the temperature of a substrate holder of the n-layer deposition chamber should be controlled to be set to a deposition temperature (S12). The deposition temperature corresponds to an actual temperature of the substrate at which the n-type silicon alloy reflector is being deposited. It is suitable that the deposition temperature should be 100° C. to 200° C. If the deposition temperature is lower than 100° C., the deposition rate of the thin film is reduced and a poor thin film having a high defect density is deposited. If the deposition temperature is higher than 200° C., the evolution of hydrogen from the i-type photoelectric conversion layer proceeds, and thus the characteristic of the solar cell is deteriorated. Also, a flexible substrate may be transformed.

After the substrate on which the i-type photoelectric conversion layer has been stacked is carried to the n-layer deposition chamber, the pressure of the n-layer deposition chamber reaches a base pressure by the operation of a high vacuum pump like a turbo molecular pump, and thereby the n-layer deposition chamber becomes in a vacuum state (S13). Here, it is recommended that the base pressure is 10⁻⁷ Torr to 10⁻⁵ Torr. A high quality thin film which is less contaminated by oxygen, nitrogen or the like may be deposited via the reduction of the base pressure. However, a deposition time becomes longer and the throughput is reduced. The greater the base pressure is, the thin film is more contaminated by oxygen, nitrogen or the like. Therefore, a high quality thin film cannot be obtained.

After the pressure of the deposition chamber reaches the base pressure, the mixed reaction gas is introduced into the deposition chamber. The mixed reaction gas includes silane (SiH₄), hydrogen (H₂), phosphine (PH₃) and source gas including the refractive index reduction element.

When the pressure of the deposition chamber reaches a predetermined deposition pressure, the pressure is constantly maintained to a predetermined pressure value by the pressure controller, which is connected to the deposition chamber, and the angle valve (S14). The deposition pressure is set to a value for obtaining the thickness uniformity, high quality characteristics and an appropriate deposition rate of the thin film. It is recommended that the deposition pressure is 1 Torr to 7 Torr. If the deposition pressure is low, the thickness uniformity and deposition rate are reduced. If the deposition pressure is too high, powder is produced at a plasma electrode or the amount of gas used is increased, and thus the manufacturing cost is increased.

When the pressure within the deposition chamber is stabilized to the deposition pressure, the mixed reaction gas is decomposed by generating RF or VHF plasma within the deposition chamber (S15). Then, the profiled n-type silicon alloy reflector is deposited on the i-type photoelectric conversion layer (S16).

In order to profile the n-type silicon alloy reflector, the flow rate, deposition temperature, deposition pressure is maintained constant. The refractive index reduction element may include oxygen, carbon or nitrogen. Carbon source gas may include methan (CH₄), ethylene (C₂H₄), acetylene (C₂H₂) and the like. Oxygen source gas may include O₂, CO₂ or the like. Nitrogen source gas may include ammonium (NH₄), nitrous oxide (N₂O), nitrogen monoxide (NO) or the like. During the deposition of the n-type silicon alloy reflector, the flow rate ratio of SiH₄ to the source gas including the refractive index reduction element is increased or decreased gradually or stepwisely depending on time. As a result, the n-type silicon alloy reflector is formed on the i-type photoelectric conversion layer.

The concentration of the refractive index reduction element in the n-type silicon alloy reflector may be decreased or increased gradually or stepwisely with the increase in a distance from a sunlight incident side.

Accordingly, the n-type silicon alloy reflector is formed which includes n-type silicon carbide, n-type silicon nitride or n-type silicon oxide (S16).

The deposition of the profiled n-type silicon alloy reflector is completed by turning off the power of plasma (S17).

As another method for profiling the n-type silicon alloy reflector, there is a method for alternately depositing the first sub-layer and the second sub-layer, both of which have mutually different refractive index reduction element contents.

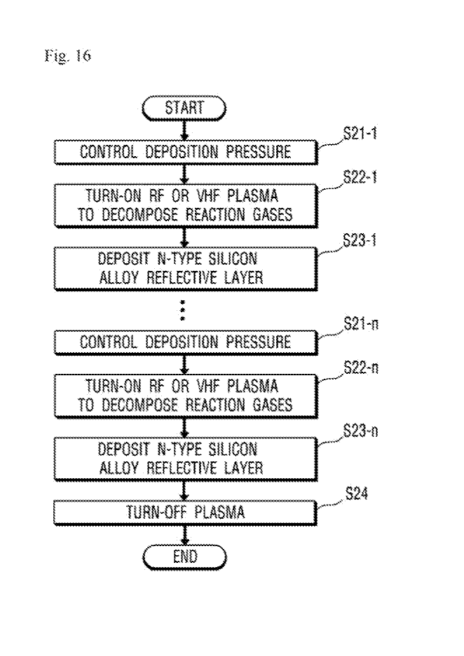

FIG. 16 is a flowchart showing the method for profiling the n-type silicon alloy reflector.

Referring to FIG. 16, the pressure of the pressure controller is set to a deposition pressure of the first sub-layer having a low refractive index reduction element content, and then the deposition pressure is controlled by controlling the angle valve (S21-1). Since the deposition pressure is set to a value for obtaining the thickness uniformity, high quality characteristics and an appropriate deposition rate of the thin film, it is recommended that the deposition pressure is 1 Torr to 7 Torr. If the deposition pressure is low, the thickness uniformity and deposition rate are reduced. If the deposition pressure is too high, powder is produced at a plasma electrode or the amount of gas used is increased, and thus the manufacturing cost is increased.

When the pressure within the deposition chamber is stabilized to the deposition pressure, the mixed reaction gas is decomposed by generating RF or VHF plasma within the deposition chamber (S22-1), and then the first sub-layer is stacked (S23-1). Subsequently, the setting for the flow rate of the mass flow controller for the deposition of the second sub-layer including silicon oxide, silicon carbide or silicon nitride is changed without turning off the power of plasma. Then, the second sub-layer may be stacked.

The first sub-layer and the second sub-layer are alternately deposited and may be stacked maximally tour times. That is, the maximum value of “n” of FIG. 16 is 4.

The total thickness of the n-type silicon alloy reflector is equal to or larger than 20 nm and equal to or less than 80 nm. When the total thickness is less than 20 nm, a strong electric field cannot be formed in the i-type photoelectric conversion layer, and thus the open circuit voltage of the solar cell becomes lower and the internal reflection is difficult to increase. When the total thickness is larger than 80 nm, the light absorption in the n-type silicon alloy reflector increases and the short circuit current is reduced. Therefore, the conversion efficiency is reduced.

An average hydrogen dilution ratio (i.e., the flow rate ratio of H₂/SiH₄ gas for the profiled n-type silicon alloy reflector) is selected within a range between 100 and 1,000. If the hydrogen dilution ratio is greater than 100, the electric conductivity can be prevented from being decreased. If the hydrogen dilution ratio is less than 1,000, the n-type silicon alloy reflector can be prevented from becoming porous. Additionally, if the hydrogen dilution ratio is too high, the deposition rate becomes lower and the manufacturing cost increases.

Lastly, the deposition of the profiled n-type silicon alloy reflector is completed by turning off the power of plasma-turn off (S24). Then, the mass flow controllers block the flows of all the reaction gas and the angle valve connected to the pressure controller is fully opened, and thus the residual mixed reaction gas in the deposition chamber is sufficiently evacuated to an exhaust line. Then, the next process in which the back electrode is deposited is subsequently performed.

Accordingly, the silicon thin film solar cell manufactured through the aforementioned process makes use of the n-type silicon alloy reflector profiled with the refractive index reduction element. With this, the active internal reflection is caused within the profiled n-type silicon alloy reflector. As a result, the short circuit current is increased and the conversion efficiency of the thin film silicon solar cell is improved.

The above-described method for manufacturing the p-i-n type single-junction solar cell can be applied to the multi-junction thin film solar cell and can be also applied to the n-i-p type single-junction or multi-junction thin film solar cell.

As described above, it will be appreciated by those skilled in the art that the present invention can be embodied in other specific forms without departing from its spirit or essential characteristics. Therefore, the foregoing embodiments and advantages are merely exemplary and are not to be construed as limiting the present invention. The present teaching can be readily applied to other types of apparatuses. The description of the foregoing embodiments is intended to be illustrative, and not to limit the scope of the claims. Many alternatives, modifications, and variations will be apparent to those skilled in the art. In the claims, means-plus-function clauses are intended to cover the structures described herein as performing the recited function and not only structural equivalents but also equivalent structures.

What is claimed is:

1. A thin film silicon solar cell comprising:
a substrate;
a first electrode which is stacked on the substrate;
a unit cell which is stacked on the first electrode; and
a second electrode which is stacked on the unit cell,
wherein the unit cell includes a p-type window layer, an i-type photoelectric conversion layer and an n-type layer, and wherein the n-type layer includes an n-type silicon alloy reflector profiled such that a concentration of a refractive index reduction element is increased or decreased with the increase in a distance from a light incident side.

2. The thin film silicon solar cell of claim 1, wherein a thickness of the n-type silicon alloy reflector is equal to larger than 20 nm and equal to or less than 80 nm.

3. The thin film silicon solar cell of claim 1, comprising at least one of oxygen, nitrogen or carbon as the refractive index reduction element, wherein an average content of the refractive index reduction element of the n-type silicon alloy reflector is equal to or more than 10 atomic % and equal to or less than 50 atomic %.

4. The thin film silicon solar cell of claim 1, wherein an average impurity doping concentration of the n-type silicon alloy reflector is equal to or higher than 1×10¹⁹/cm³ and equal to or less than 1×10²¹/cm³.

5. The thin film silicon solar cell of claim 1, wherein an average hydrogen concentration of the n-type silicon alloy reflector is equal to or more than 5 atomic % and equal to or less than 25 atomic %.

6. The thin film silicon solar cell of claim 1, wherein, when the n-type layer is measured by Raman spectroscopy by irradiating laser with a wavelength of 633 nm to the back side of the n-type silicon alloy reflector, a crystal volume fraction is equal to or greater than 0% and equal to or less than 25%.

7. The thin film silicon solar cell of claim 1, wherein the n-type layer further comprises a relatively slightly hydrogen-diluted n-type amorphous silicon layer than the profiled n-type silicon alloy reflector between the i-type photoelectric conversion layer and the n-type silicon alloy reflector, and wherein a thickness of the relatively slightly hydrogen-diluted n-type amorphous silicon layer is equal to or larger than 3 nm and equal to or less than 7 nm.

8. The thin film silicon solar cell of claim 1, wherein the n-type silicon alloy reflector further comprises a back reflector, and wherein the back reflector is formed of zinc oxide (ZnO) and has a thickness equal to or larger than 2 nm and equal to or less than 5 nm.

9. The thin film silicon solar cell of claim 1, further comprising a metal grid formed on either the first electrode or the second electrode.

10. The thin film silicon solar cell of claim 1, further comprising an additional unit cell between the unit cell and any one of the first electrode and the second electrode, and the additional unit cell comprises the p-type window layer, the i-type photoelectric conversion layer and the n-type layer.

11. The thin film silicon solar cell of claim 10, wherein, when the thin film silicon solar cell has a double-junction structure and the n-type layer is measured by Raman spectroscopy by irradiating laser with a wavelength of 633 nm to the back side of a bottom cell, a crystal volume fraction is equal to or greater than 30% and equal to or less than 85%.

12. A thin film silicon solar cell comprising:
a substrate;
a first electrode which is stacked on the substrate;
a unit cell which is stacked on the first electrode; and
a second electrode which is stacked on the unit cell,
wherein the unit cell includes a p-type window layer, an i-type photoelectric conversion layer and an n-type layer, and wherein the n-type layer includes an n-type silicon alloy reflector in which a first sub-layer having a relatively low refractive index reduction element content and a second sub-layer having a relatively high refractive index reduction element content are alternately stacked.

13. The thin film silicon solar cell of claim 12, wherein a thickness of the n-type silicon alloy reflector is equal to larger than 20 nm and equal to or less than 80 nm.

14. The thin film silicon solar cell of claim 12, comprising at least one of oxygen, nitrogen or carbon as the refractive index reduction element, wherein an average content of the refractive index reduction element of the first sub-layer is equal to or more than O atomic % and equal to or less than 20 atomic % and a thickness of the first sub-layer is equal to or larger than 2.5 nm and equal to or less than 10 nm, and wherein an average content of the refractive index reduction element of the second sub-layer is equal to or more than 20 atomic % and equal to or less than 50 atomic % and a thickness of the second sub-layer is equal to or larger than 2.5 nm and equal to or less than 10 nm.

15. The thin film silicon solar cell of claim 12, wherein an average impurity doping concentration of the n-type silicon alloy reflector is equal to or higher than 1×10¹⁹/cm³ and equal to or less than 1×10²¹/cm³.

16. The thin film silicon solar cell of claim 12, wherein an average hydrogen concentration of the n-type silicon alloy reflector is equal to or more than 5 atomic % and equal to or less than 25 atomic %.

17. The thin film silicon solar cell of claim 12, wherein, when the n-type layer is measured by Raman spectroscopy by irradiating laser with a wavelength of 633 nm to the back side of the n-type silicon alloy reflector, a crystal volume fraction is equal to or greater than 0% and equal to or less than 25%.

18. The thin film silicon solar cell of claim 12, wherein the n-type layer further comprises a relatively slightly hydrogen-diluted n-type amorphous silicon layer than the profiled n-type silicon alloy reflector between the i-type photoelectric conversion layer and the n-type silicon alloy reflector, and wherein a thickness of the relatively slightly hydrogen-diluted n-type amorphous silicon layer is equal to or larger than 3 nm and equal to or less than 7 nm.

19. The thin film silicon solar cell of claim 12, wherein the n-type silicon alloy reflector further comprises a back reflector, and wherein the back reflector is formed of zinc oxide (ZnO) and has a thickness equal to or larger than 2 nm and equal to or less than 5 nm.

20. The thin film silicon solar cell of claim 12, further comprising a metal grid formed on either the first electrode or the second electrode.

21. The thin film silicon solar cell of claim 12, further comprising an additional unit cell between the unit cell and any one of the first electrode and the second electrode, and the additional unit cell comprises the p-type window layer, the i-type photoelectric conversion layer and the n-type layer; and wherein, when the thin film silicon solar cell has a double-junction structure and the n-type layer is measured by Raman spectroscopy by irradiating laser with a wavelength of 633 nm to the back side of a bottom cell, a crystal volume fraction is equal to or greater than 30% and equal to or less than 85%.
